(19) United States
(12) Patent Application Publication
(10) Pub. No.: US 2025/0253297 A1
(43) Pub. Date: Aug. 7, 2025

(54) SEMICONDUCTOR PACKAGE

(71) Applicant: SAMSUNG ELECTRONICS CO., LTD., Suwon-si (KR)

(72) Inventor: Hyunsoo CHUNG, Suwon-si (KR)

(73) Assignee: SAMSUNG ELECTRONICS CO., LTD., Suwon-si (KR)

(21) Appl. No.: 18/977,447

(22) Filed: Dec. 11, 2024

(30) Foreign Application Priority Data
Feb. 6, 2024 (KR) 10-2024-0018424

(51) Int. Cl. H01L 25/16; H01L 23/13; H01L 23/15; H01L 23/31; H01L 23/373; H01L 23/498; H01L 23/538; H01L 25/00; H10B 80/00

(52) U.S. Cl. CPC H01L 25/162; H01L 23/13; H01L 23/3738; H01L 23/5385; H01L 25/50; H01L 23/15; H01L 23/3107; H01L 23/49894; H10B 80/00

(57) ABSTRACT

A semiconductor package is provided and includes: a glass substrate including a cavity; a logic chip within the cavity; a memory device on the glass substrate and the logic chip; a first redistribution structure between the memory device and the glass substrate and connected to the memory device and the glass substrate; a second redistribution structure below the glass substrate and connected to the glass substrate and the logic chip; and a package encapsulation layer that surrounds the memory device and the logic chip on the second redistribution structure.

### CROSS-REFERENCE TO RELATED APPLICATION

This application is based on and claims priority under 35 U.S.C. § 119 to Korean Patent Application No. 10-2024-0018424, filed on Feb. 6, 2024, in the Korean Intellectual Property Office, the disclosure of which is incorporated by reference herein in its entirety.

### BACKGROUND

### 1. Field

Embodiments of the present disclosure relate to a semiconductor package, and more particularly, to a semiconductor package including a plurality of semiconductor chips.

### 2. Brief Description of Related Art

With the rapid development of the electronics industry and user demands, electronic products are becoming smaller and lighter. To this end, semiconductor packages mounted on electronic products are required to have larger capacities or various functions while becoming smaller in volume. Accordingly, a semiconductor package including a plurality of semiconductor chips is being developed.

### SUMMARY

According to embodiments of the present disclosure, a semiconductor package including a plurality of semiconductor chips is provided.

According to embodiments of the present disclosure, a semiconductor package is provided and includes: a glass substrate including a cavity; a logic chip within the cavity; a memory device on the glass substrate and the logic chip; a first redistribution structure between the memory device and the glass substrate and connected to the memory device and the glass substrate; a second redistribution structure below the glass substrate and connected to the glass substrate and the logic chip; and a package encapsulation layer that surrounds the memory device and the logic chip on the second redistribution structure.

According to embodiments of the present disclosure, a semiconductor package is provided and includes: a glass substrate including a cavity, the glass substrate including a glass body that includes a first surface and a second surface opposite to the first surface; a logic chip within the cavity; a pair of memory devices on the first surface of the glass body and the logic chip, the pair of memory devices spaced apart from each other in a horizontal direction of the semiconductor package; a first redistribution structure between the pair of memory devices and the first surface of the glass body; a second redistribution structure on the second surface of the glass body and connected to the glass substrate and the logic chip; a heat dissipation member between the pair of memory devices on a top surface of the logic chip; and a first package encapsulation layer surrounding the pair of memory devices and the heat dissipation member on the second redistribution structure.

According to embodiments of the present disclosure, a semiconductor package is provided and includes: a glass substrate including a cavity, the glass substrate including a glass body that including a first surface and a second surface opposite to the first surface, and the glass substrate further including a through electrode extending from the first surface to the second surface; a logic chip within the cavity; a first memory device on the first surface of the glass body and the logic chip and including a plurality of first semiconductor chips stacked in a vertical direction of the semiconductor package; a first redistribution structure between the first memory device and the first surface of the glass body and connected to the first memory device and the glass substrate; a second redistribution structure on the second surface of the glass body and connected to the glass substrate and the logic chip; a second memory device spaced from the first memory device in a horizontal direction of the semiconductor package and including a plurality of second semiconductor chips stacked in the vertical direction; a heat dissipation member between the first memory device and the second memory device on a top surface of the logic chip; and a package encapsulation layer surrounding the first memory device, the second memory device, and the heat dissipation member on the second redistribution structure. The first redistribution structure includes: a first insulating layer in contact with the first surface of the glass body; and a first conductive pad in the first insulating layer and bonded to the through electrode. The second redistribution structure includes: a second insulating layer in contact with the second surface of the glass body; and a second conductive pad in the second insulating layer and bonded to the through electrode, wherein a width of the second conductive pad is greater than a width of the first conductive pad in the horizontal direction.

Aspects of embodiments of the present disclosure are not limited to the aspects mentioned above, and other aspects of embodiments of the present disclosure may be clearly understood by those skilled in the art from the description below.

### BRIEF DESCRIPTION OF DRAWINGS

Embodiments will be more clearly understood from the following detailed description taken in conjunction with the accompanying drawings in which:

FIG. 1 is a cross-sectional view of a semiconductor package according to an embodiment;

FIG. 2 is an enlarged view of area CX1 in FIG. 1;

FIG. 3 is an enlarged view of area CX2 in FIG. 1;

FIG. 4 is a plan view of the semiconductor package shown in FIG. 1;

FIG. 5 is a plan view of a semiconductor package according to another embodiment;

FIGS. 6 and 7 are cross-sectional views of semiconductor packages according to other embodiments;

FIGS. 8 to 18 are cross-sectional views of a semiconductor package to sequentially show a manufacturing process of the semiconductor package according to an embodiment;

FIG. 19 is a schematic block diagram of an example of a memory system having a semiconductor package according to an embodiment; and

FIG. 20 is a schematic block diagram of an example of an information processing system having a semiconductor package according to an embodiment.

### DETAILED DESCRIPTION

Hereinafter, example embodiments of the present disclosure are described in detail with reference to the accompanying drawings. However, the present disclosure is not limited to the example embodiments described below and embodiments of the present disclosure may be embodied in various other forms. The following description is intended fully convey the scope of the present disclosure to those skilled in the art.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

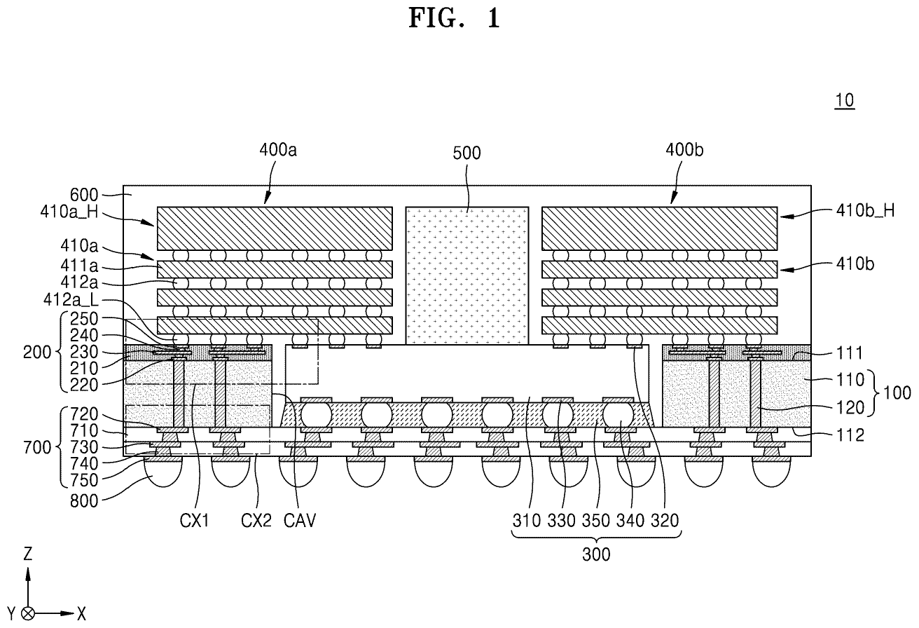

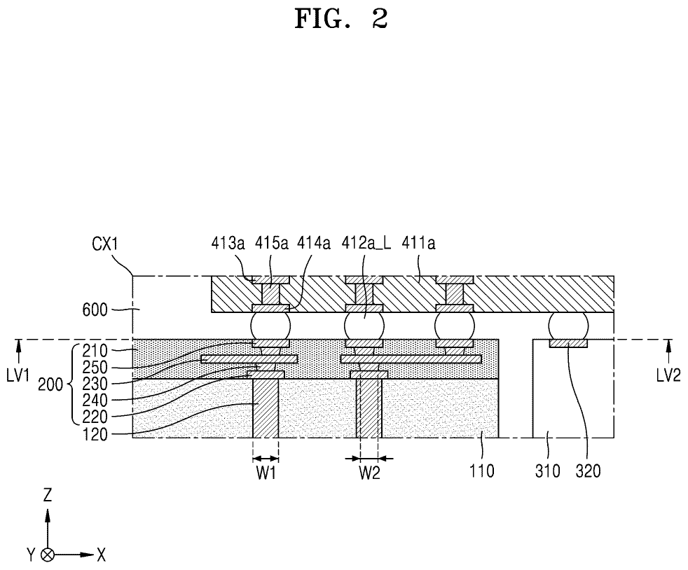

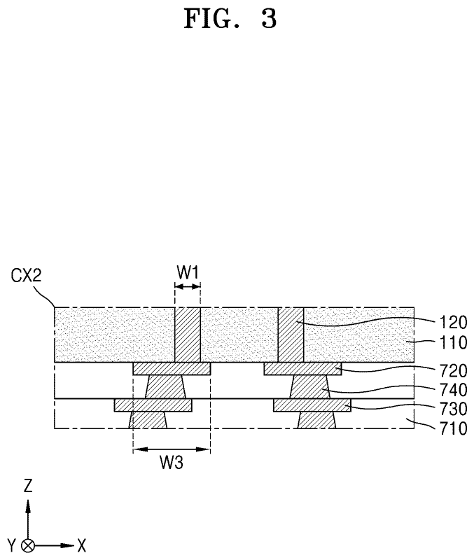

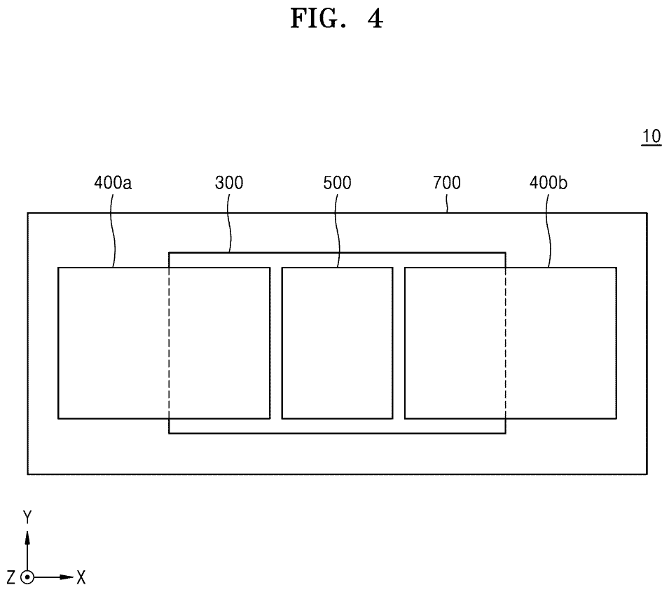

FIG. 1 is a cross-sectional view of a semiconductor package 10 according to an embodiment, and FIG. 2 is an enlarged view of an area CX1 in FIG. 1. FIG. 3 is an enlarged view of an area CX2 in FIG. 1, and FIG. 4 is a plan view of the semiconductor package 10 shown in FIG. 1.

Referring to FIGS. 1 to 4, the semiconductor package 10 according to an embodiment may include a glass substrate 100, a first redistribution structure 200, a logic chip 300, a plurality of memory devices (e.g., a first memory device 400a and a second memory device 400b), a heat dissipation member 500, a package encapsulation layer 600, a second redistribution structure 700, and an external connection terminal 800.

The glass substrate 100 may include a glass body 110 and through electrodes 120. The glass body 110 has a top surface parallel to a first horizontal direction (X direction) and a second horizontal direction (Y direction), wherein the top surface of the glass body 110 may be defined as a first surface 111 thereof, and a bottom surface of the glass body 110 opposite to the top surface thereof may be defined as a second surface 112 thereof. The glass body 110 may form a cavity CAV at its center from a horizontal view. The cavity CAV may penetrate the glass body 110. Depending on an embodiment, the width of the cavity CAV in the first horizontal direction (X direction) may be greater than half the width of the glass body 110 in the first horizontal direction (X direction). According to an embodiment, the depth of the cavity CAV in a vertical direction (Z direction) is equal to the height of the glass body 110 in the vertical direction (Z direction). Herein, the first horizontal direction (X direction) may be defined as a direction parallel to the first surface 111 of the glass body 110, and the second horizontal direction (Y direction) may be defined as a direction parallel to the first surface 111 of the glass body 110 and perpendicular to the first horizontal direction (X direction).

The through electrodes 120 may extend from the first surface 111 to the second surface 112 of the glass body 110 to fill holes penetrating the glass body 110. Herein, the vertical direction (Z direction) may be defined as a direction extending through the glass body 110. The through electrodes 120 may be configured to electrically connect the first redistribution structure 200 disposed on the first surface 111 of the glass body 110 to the second redistribution structure 700 disposed on the second surface 112 of the glass body 110.

According to an embodiment, the glass substrate 100 may include glass but is not limited thereto. The glass substrate 100 may include, for example, prepreg including insulating resin, inorganic filler, and glass fiber. The through electrodes 120 may include a conductive material, such as copper (Cu), gold (Au), silver (Ag), nickel (Ni), tungsten (W), aluminum (Al), or a combination thereof. In some embodiments, the through electrodes 120 may further include a barrier material to prevent the conductive material from diffusing out of the through electrodes 120. The barrier material may include, for example, titanium (Ti), tantalum (Ta), titanium nitride (TiN), tantalum nitride (TaN), or a combination thereof.

The first redistribution structure 200 may be disposed on the first surface 111 of the glass body 110. The width of the first redistribution structure 200 in the lateral direction (X direction and/or Y direction) may correspond to the width of the glass body 110 in the lateral direction (X direction and/or Y direction). The first redistribution structure 200 may include a first insulating layer 210, first lower connection pads 220, a first wiring pattern 230, first vias 240, and first upper connection pads 250.

The first insulating layer 210 may cover the first surface 111 of the glass body 110. The first insulating layer 210 may be in contact with the first surface 111 of the glass body 110. The width of the first insulating layer 210 in the lateral direction (X direction and/or Y direction) may correspond to the width of the glass body 110 in the lateral direction (X direction and/or Y direction). Additionally, the length of the first insulating layer 210 in the vertical direction (Z direction) may be less than the length of the glass body 110 in the vertical direction (Z direction).

The first lower connection pads 220, the first wiring pattern 230, the first vias 240, and the first upper connection pads 250 may be buried inside the first insulating layer 210. Bottom surfaces of the first lower connection pads 220 may be flush with the bottom surface of the first insulating layer 210, and the first lower connection pads 220 may be in contact with the through electrodes 120. The first lower connection pads 220 may be electrically and physically connected to the through electrodes 120 to receive electrical signals from the second redistribution structure 700 or to transmit electrical signals to the second redistribution structure 700. According to an embodiment, the width of the first lower connection pad 220 in the lateral direction (X direction and/or Y direction) may be greater than the width W1 of the through electrode 120 in the lateral direction (X direction and/or Y direction).

According to an embodiment, the first wiring pattern 230 may be buried inside the first insulating layer 210 and extend in the lateral direction (X direction and/or Y direction). In FIGS. 1 and 2, the first wiring pattern 230 is shown as one in the vertical direction (Z direction). However, depending on an embodiment, a plurality of first wiring patterns 230 may be arranged at different vertical levels. The plurality of first vias 240 may contact the top surface and the bottom surface of the first wiring pattern 230, respectively.

According to an embodiment, the first vias 240 may be buried inside the first insulating layer 210 and extend in the vertical direction (Z direction). The number of first vias 240 may be plural. The plurality of first vias 240 may be arranged at different vertical levels. Some of the plurality of first vias 240 between the first wiring pattern 230 and the first lower connection pads 220 may provide an electrical connection path between the first wiring pattern 230 and the first lower connection pads 220. In addition, others of the plurality of first vias 240 between the first upper connection pads 250 and the first wiring pattern 230 may provide an electrical connection path between the first upper connection pads 250 and the first wiring pattern 230. The first via 240 may have a tapered shape of which the diameter narrows towards the glass substrate 100 in the vertical direction (Z direction).

According to an embodiment, the top surfaces of the first upper connection pads 250 may be flush with the top surface of the first insulating layer 210, and the first upper connection pads 250 may be in contact with lowermost memory connection terminals 412a_L of a lowermost one of memory chips 410a. The first upper connection pads 250 may be electrically and physically connected to the through electrodes 120 to receive electrical signals from the memory devices (e.g., the first memory device 400a and the second memory device 400b) or to transmit electrical signals to the memory devices (e.g., the first memory device 400a and the second memory device 400b). The first redistribution structure 200 may be formed by repeating the patterning process.

The first insulating layer 210 may include, for example, an inorganic insulating material, an organic insulating material, or a combination thereof. The inorganic insulating material may include, for example, silicon oxide, silicon nitride, or a combination thereof. The organic insulating material may include, for example, polyimide, epoxy resin, or a combination thereof. The first lower connection pads 220, the first wiring pattern 230, the first vias 240, and the first upper connection pads 250 may include a conductive material, such as Cu, Au, Ag, Ni, W, Al, or a combination thereof. In some embodiments, the first lower connection pads 220, the first wiring pattern 230, the first vias 240, and the first upper connection pads 250 may further include a barrier material to prevent the conductive material from diffusing out of the first lower connection pads 220, the first wiring pattern 230, the first vias 240, and the first upper connection pads 250. The barrier material may include, for example, Ti, Ta, TiN, TaN, or a combination thereof.

According to an embodiment, the logic chip 300 may be mounted within the cavity CAV of the glass substrate 100. The logic chip 300 may be placed on the second redistribution structure 700 and spaced apart from sides of the glass substrate 100.

The logic chip 300 may include a logic chip body 310, logic chip upper pads 320, logic chip lower pads 330, logic chip connection terminals 340, and underfill 350.

A bottom surface of the logic chip body 310 facing the second redistribution structure 700 may be defined as an active surface thereof. The logic chip body 310 may include, for example, silicon. Alternatively, the logic chip body 310 may include a semiconductor element, such as germanium (Ge), or a compound semiconductor, such as silicon carbide (SiC), gallium arsenide (GaAs), indium arsenide (InAs), and indium phosphide (InP). Alternatively, the logic chip body 310 may have a silicon on insulator (SOI) structure. For example, the logic chip body 310 may include a buried oxide (BOX) layer. The logic chip body 310 may include a conductive region such as, for example, a well doped with an impurity or a structure doped with an impurity. Additionally, the logic chip body 310 may have various device isolation structures, such as a shallow trench isolation (STI) structure.

The logic chip 300 may include, for example, a system-on-chip, a central processing unit (CPU) chip, a graphics processing unit (GPU) chip, or an application processor (AP) chip. The logic chip 300 may execute applications supported by the semiconductor package 10 using the plurality of memory devices (e.g., the first memory device 400a and the second memory device 400b). For example, the logic chip 300 may include at least one from among processors, such as a CPU, an AP, a GPU, a neural processing unit (NPU), a tensor processing unit (TPU), a vision processing unit (VPU), an image signal processor (ISP), and a digital signal processor (DSP), to execute specialized operations.

According to an embodiment, the plurality of logic chip upper pads 320 may be arranged in a lateral direction (X direction and/or Y direction) on the top surface of the logic chip body 310. According to an embodiment, the top surfaces of the logic chip upper pads 320 may be flush with the top surface of the logic chip body 310, and the logic chip upper pads 320 may be in contact with the lowermost memory connection terminals 412a_L of the lowermost one of the memory chips 410a. According to embodiments, logic chip through vias that penetrate the logic chip body 310 in the vertical direction (Z direction) may be positioned inside the logic chip body 310. The logic chip upper pads 320 may be electrically and physically connected to the logic chip through vias to receive electrical signals from the memory devices (e.g., the first memory device 400a and the second memory device 400b) or to transmit electrical signals to the memory devices (e.g., the first memory device 400a and the second memory device 400b).

According to an embodiment, the plurality of logic chip lower pads 330 may be arranged on the bottom surface of the logic chip body 310 in the lateral direction (X direction and/or Y direction). According to an embodiment, the bottom surfaces of the logic chip lower pads 330 may be flush with the bottom surface of the logic chip body 310, and the logic chip lower pads 330 may be in contact with the logic chip connection terminals 340. The logic chip lower pads 330 may be electrically and physically connected to the logic chip through-vias to receive electrical signals from the second redistribution structure 700 or to transmit electrical signals to the second redistribution structure 700.

According to an embodiment, the plurality of logic chip connection terminals 340 may be attached to the plurality of logic chip lower pads 330 of the logic chip body 310. The logic chip connection terminals 340 may include a conductive material, such as tin (Sn), lead (Pb), Ag, Cu, or a combination thereof. The logic chip connection terminals 340 may be formed using, for example, solder balls. The logic chip connection terminals 340 may connect the logic chip 300 to the second redistribution structure 700. The logic chip connection terminals 340 may be attached to second upper connection pads 720 of the second redistribution structure 700.

According to an embodiment, the underfill 350 is formed between the logic chip body 310 and the second redistribution structure 700. The underfill 350 may fill all the space between the logic chip body 310 and the second redistribution structure 700. The underfill 350 may completely surround the logic chip connection terminals 340. The underfill 350 may have a wider horizontal cross-sectional area toward the second redistribution structure 700 from the logic chip body 310. For example, a horizontal cross-sectional area of the underfill 350 may increase in a direction toward the second redistribution structure 700 from the logic chip body 310.

The underfill 350 may be formed by, for example, a capillary under-fill method. The underfill 350 may include, for example, epoxy resin. The underfill 350 may be mixed with fillers. The fillers may include, for example, silica. For example, the fillers may have a size of about 0.1 μm to about several μm or less and may have an average size of about 0.3 μm to about 1 μm. For example, the underfill 350 may be mixed with fillers having a mass of about 55% to about 75%. That is, a ratio of the fillers to the underfill 350 may be about 55 wt % to about 75 wt %.

According to an embodiment, the width of the logic chip lower pads 330 in the lateral direction (X direction and/or Y direction) may be greater than the width of the logic chip upper pads 320 in the lateral direction (X direction and/or Y direction). According to an embodiment, the pitch and the width of the second upper connections pads 720 of the second redistribution structure 700 in the lateral direction (X direction and/or Y direction) may be greater than the pitch and the width of the first upper connections pads 250 of the first redistribution structure 200 in the lateral direction (X direction and/or Y direction). The first upper connections pads 250 are connected to the memory devices (e.g., the first memory device 400a and the second memory device 400b) through small connection terminals (e.g., memory chip connection terminals 412a) and the second upper connection pads 720 are connected to the logic chip 300 through large connection terminals (e.g., logic chip connection terminals 340). Since the logic chip upper pads 320 are also connected to the memory devices (e.g., the first memory device 400a and the second memory device 400b), the pitch and the width of the logic chip upper pads 320 in the lateral direction (X direction and/or Y direction) may correspond to the pitch and width of the first upper connection pads 250 in the lateral direction (X direction and/or Y direction). Therefore, the pitch and the width of the logic chip upper pads 320 in the lateral direction (X direction and/or Y direction) may be greater than the pitch and width of the logic chip lower pads 330 in the lateral direction (X direction and/or Y direction).

The logic chip upper pads 320 and the logic chip lower pads 330 may include a conductive material, such as Cu, Au, Ag, Ni, W, Al, or a combination thereof. In some embodiments, the logic chip upper pads 320 and the logic chip lower pads 330 may further include a barrier material to prevent the conductive material from diffusing out of the through electrodes 120. The barrier material may include, for example, Ti, Ta, TiN, TaN, or a combination thereof.

According to an embodiment, the plurality of memory devices (e.g., the first memory device 400a and the second memory device 400b) may include a first memory device 400a and a second memory device 400b spaced apart from the first memory device 400a in the first horizontal direction (X direction).

The first memory device 400a may include a plurality of first memory chips 410a stacked in the vertical direction (Z direction). As shown in FIGS. 1 and 2, each of the plurality of first memory chips 410a may include a first memory chip body 411a, first memory chip connection terminals 412a, first chip front pads 414a, first chip back pads 413a, and first chip through electrodes 415a.

The first memory chip body 411a may have an active surface and an inactive surface that are opposite to each other. Within the semiconductor package 10, the first memory chips 410a may be arranged such that the active surface of the first memory chip body 411a faces downward and the inactive surface thereof faces upward. Therefore, unless otherwise stated herein, the top surface of the first memory chip 410a in the semiconductor package 10 refers to the inactive surface of the first memory chip body 411a faces, and the bottom surface of the first memory chip 410a refers to the active surface of the first memory chip body 411a. However, with respect to the first memory chip 410a, the bottom surface of the first memory chip 410a may be referred to as a front surface of the first memory chip 410a and the top surface of the first memory chip 410a may be referred to as a back surface of the first memory chip 410a.

According to embodiments, semiconductor devices may be disposed on the active surface of the first memory chip body 411a.

The semiconductor devices may be formed on the active surface of the first memory chip body 411a, the plurality of first chip front pads 414a and the plurality of first chip back pads 413a may be formed on or at the active surface and the inactive surface of the first memory chip body 411a, respectively, and the plurality of first chip through electrodes 415a may vertically penetrate at least a portion of the first memory chip body 411a to electrically connect the plurality of first chip front pads 414a to the plurality of first chip back pads 413a. The plurality of first memory chip connection terminals 412a may be bonded to the plurality of first chip front pads 414a, respectively.

The first chip through electrodes 415a, the first chip back pads 413a, and first chip front pads 414a may include a conductive material, such as Cu, Au, Ag, Ni, W, Al, or a combination thereof. In some embodiments, the first chip through electrodes 415a, the first chip back pads 413a, and first chip front pads 414a may further include a barrier material to prevent the conductive material from diffusing out of the through electrodes 120. The barrier material may include, for example, Ti, Ta, TiN, TaN, or a combination thereof.

The first memory chip body 411a may include a semiconductor material, such as a group IV semiconductor material, a group III-V semiconductor material, a group II-VI semiconductor material, or a combination thereof. The group IV semiconductor material may include, for example, silicon (Si), Ge, or a combination thereof. The group III-V semiconductor material may include, for example, gallium arsenide (GaAs), indium phosphorus (InP), gallium phosphorus (GaP), indium arsenide (InAs), indium antimony (InSb), indium gallium arsenide (InGaAs), or a combination thereof. The group II-VI semiconductor material may include, for example, zinc telluride (ZnTe), cadmium sulfide (CdS), or a combination thereof.

The first memory chip connection terminals 412a may include a conductive material, such as Sn, Pb, Ag, Cu, or a combination thereof. The first memory chip connection terminals 412a may be formed using, for example, solder balls.

The plurality of first memory chip connection terminals 412a may be attached to the plurality of first chip front pads 414a of each of the first memory chips 410a, respectively. The plurality of first memory chip connection terminals 412a between the plurality of first chip front pads 414a of an upper one of the first memory chips 410a and the plurality of first chip back pads 413a of a lower one of the first memory chips 410a may electrically connect the plurality of first memory chips 410a at different vertical levels.

The first memory chip 410a located at the top among the plurality of first memory chips 410a stacked in the vertical direction (Z direction) may be defined as an uppermost one of the first memory chips 410a. The thickness of the uppermost one of the first memory chips 410a in the vertical direction (Z direction) may be greater than the thickness of the other ones of the first memory chips 410a in the vertical direction (Z direction).

Among the plurality of first memory chip connection terminals 412a, the first memory chip connection terminals 412a attached to the first memory chip 410a located at the bottom among the plurality of first memory chips 410a may be defined as lowermost one of the first memory chip connection terminals 412a. The lowermost one of the first memory chip connection terminals 412a may be bonded to the first upper connection pads 250 of the first redistribution structure 200 and the logic chip upper pads 320 of the logic chip 300.

In FIG. 1, the first memory device 400a is shown as including four first memory chips 410a but is not limited thereto. For example, the first memory device 400a may include two or more first memory chips 410a. In some embodiments, the first memory device 400a may include a multiple of four first memory chips 410a. The plurality of first memory chips 410a may be sequentially stacked in the vertical direction (Z direction). The first memory device 400a may include dynamic random-access memory (DRAM), static random-access memory (SRAM), flash memory, electrically erasable and programmable read-only memory (EEPROM), phase-change random-access memory (PRAM), magnetic random-access memory (MRAM), or resistive random-access memory (RRAM).

In some embodiments, the first memory device 400a may not include memory cells. The first memory device 400a may include a test logic circuit, such as serial-parallel conversion circuit, design for test (DFT), joint test action group (JTAG), and memory built-in self-test (MBIST), and a signal interface circuit, such as a physical layer (PHY). According to an embodiment, the plurality of first memory chips 410a may include memory cell chips having high bandwidth memory (HBM) DRAM cells. The first memory chip 410a may be referred to as a slave chip or a memory cell chip.

The second memory device 400b may be spaced apart from the first memory device 400a in the first horizontal direction (X direction) with the heat dissipation member 500 positioned therebetween. Since the second memory device 400b has substantially the same structure as the first memory device 400a, repeated description thereof is omitted below.

According to an embodiment, the heat dissipation member 500 may be positioned on the top surface of the logic chip 300. The heat dissipation member 500 may contact the top surface of the logic chip 300 to dissipate heat generated from the logic chip 300. The heat dissipation member 500 may have a width and a length that are less than the width and the length of the logic chip 300. The heat dissipation member 500 may overlap with the center of the logic chip 300 in a plan view.

Additionally, the heat dissipation member 500 may include a dummy chip. That is, a dummy chip determined to be defective in the semiconductor manufacturing process may be used as the heat dissipation member 500. Accordingly, the heat dissipation member 500 may include silicon, which is a material of the dummy chip. According to embodiments, a thermal interface material (TIM) may be positioned between the heat dissipation member 500 and the top surface of the logic chip 300. The heat dissipation member 500 may include a material with a higher thermal conductivity than the thermal conductivity of the package encapsulation layer 600. The heat dissipation member 500 may be configured to radiate heat generated from the logic chip 300 or heat generated from the first memory device 400a and the second memory device 400b spaced apart from each other in the first horizontal direction (X direction).

According to an embodiment, on the top surface of the second redistribution structure 700, the package encapsulation layer 600 may seal the logic chip 300, the first memory device 400a, the second memory device 400b, and the heat dissipation member 500. Additionally, the package encapsulation layer 600 may be positioned within the cavity CAV between the logic chip 300 and the glass substrate 100. Accordingly, the package encapsulation layer 600 may cover sides of the glass substrate 100 and sides of the first redistribution structure 200.

A single package encapsulation layer 600 positioned within the cavity CAV of the glass substrate 100 may seal the logic chip 300 and may also seal the heat dissipation member 500, the first memory device 400a, and the second memory device 400b, each disposed on the glass substrate 100. As the single package encapsulation layer 600 seals the devices within the semiconductor package 10, warpage of the semiconductor package 10 may be reduced.

For example, the package encapsulation layer 600 may include a thermosetting resin, such as an epoxy resin, a thermoplastic resin, such as polyimide, or a resin including an inorganic filler, specifically Ajinomoto build up film (ABF), FR-4, bismaleimide triazine (BT), resin, and the like. Additionally, molding materials, such as epoxy mold compound (EMC), or photosensitive materials, such as photo imagable dielectric (PID), may be used.

According to an embodiment, the second redistribution structure 700 may be disposed on the second surface 112 of the glass body 110.

The width of the second redistribution structure 700 in the lateral direction (X direction and/or Y direction) may correspond to the width of the glass body 110 in the lateral direction (X direction and/or Y direction). The second redistribution structure 700 may include a second insulating layer 710, second lower connection pads 750, a second wiring pattern 730, second vias 740, and second upper connection pads 720.

The second insulating layer 710 may cover the second surface 112 of the glass body 110, a portion of the package encapsulation layer 600, and the underfill 350. The second insulating layer 710 may be in contact with the second surface 112 of the glass body 110. The width of the second insulating layer 710 in the lateral direction (X direction and/or Y direction) may correspond to the width of the glass body 110 in the lateral direction (X direction and/or Y direction). Additionally, the length of the second insulating layer 710 in the vertical direction (Z direction) may be less than the length of the glass body 110 in the vertical direction (Z direction).

The second lower connection pads 750, the second wiring pattern 730, the second vias 740, and the second upper connection pads 720 may be buried inside the second insulating layer 710. A plurality of the second insulating layers 710 may be provided. The plurality of second insulating layers 710 may be arranged at different vertical levels. The top surfaces of the second upper connection pads 720 may be flush with the top surface of each of the plurality of second insulating layers 710, and the uppermost one of the second upper connection pads 720 may be in contact with the bottom surfaces of the through electrodes 120. The second upper connection pads 720 may be electrically and physically connected to the through electrodes 120 to receive electrical signals from the glass substrate 100 or to transmit electrical signals to the glass substrate 100. According to an embodiment, the width W3 of the second upper connection pad 720 in the lateral direction (X direction and/or Y direction) may be greater than the width W1 of the through electrode 120 in the lateral direction (X direction and/or Y direction).

According to an embodiment, the second wiring pattern 730 may be buried inside the second insulating layer 710 and may extend in the lateral direction (X direction and/or Y direction). In FIGS. 1 and 2, the second wiring pattern 730 is shown as one in the vertical direction (Z direction). However, depending on an embodiment, a plurality of second wiring patterns 730 may be arranged at different vertical levels. The plurality of second vias 740 may be arranged to contact the top surface and the bottom surface of the second wiring pattern 730, respectively.

According to an embodiment, the second vias 740 may be buried inside the second insulating layer 710 and extend in the vertical direction (Z direction). A plurality of the second vias 740 may be provided. The plurality of second vias 740 may be arranged at different vertical levels. Some of the plurality of second vias 740 between the second wiring pattern 730 and the second upper connection pads 720 may provide an electrical connection path between the second wiring pattern 730 and the second upper connection pads 720. In addition, others of the plurality of second vias 740 between the second lower connection pads 750 and the second wiring pattern 730 may provide an electrical connection path between the second lower connection pads 750 and the second wiring pattern 730. The second via 740 may have a tapered shape of which the diameter narrows towards the glass substrate 100 in the vertical direction (Z direction).

According to an embodiment, the top surfaces of the second upper connection pads 720 may be flush with the top surface of the second insulating layer 710, and the second upper connection pads 720 may be in contact with the logic chip connection terminals 340 of the logic chip 300. The second upper connection pads 720 may be electrically and physically connected to the logic chip 300 to receive electrical signals from the logic chip 300 or to transmit electrical signals to the logic chip 300. The second redistribution structure 700 may be formed by repeating the patterning process.

As shown in FIGS. 2 and 3, the width W3 of the second upper connection pad 720 in the first horizontal direction (X direction) may be greater than the width W1 of the first lower connection pad 220 in the first horizontal direction (X direction).

The second insulating layer 710 may include, for example, an inorganic insulating material, an organic insulating material, or a combination thereof. The inorganic insulating material may include, for example, silicon oxide, silicon nitride, or a combination thereof. The organic insulating material may include, for example, polyimide, epoxy resin, or a combination thereof. The second lower connection pads 750, the second wiring pattern 730, the second vias 740, and the second upper connection pads 720 may include a conductive material, such as Cu, Au, Ag, Ni, W, Al, or a combination thereof. In some embodiments, the second lower connection pads 750, the second wiring pattern 730, the second vias 740, and the second upper connection pads 720 may further include a barrier material to prevent the conductive material from diffusing out of the second lower connection pads 750, the second wiring pattern 730, the second vias 740, and the second upper connection pads 720. The barrier material may include, for example, Ti, Ta, TiN, TaN, or a combination thereof.

According to an embodiment, the external connection terminals 800 may be respectively attached to the second lower connection pads 750. The external connection terminals 800 may be configured to electrically connect the semiconductor package 10 to an external device. The external connection terminals 800 may have substantially the same material as a material of the logic chip connection terminals 340 or the memory chip connection terminals 412a.

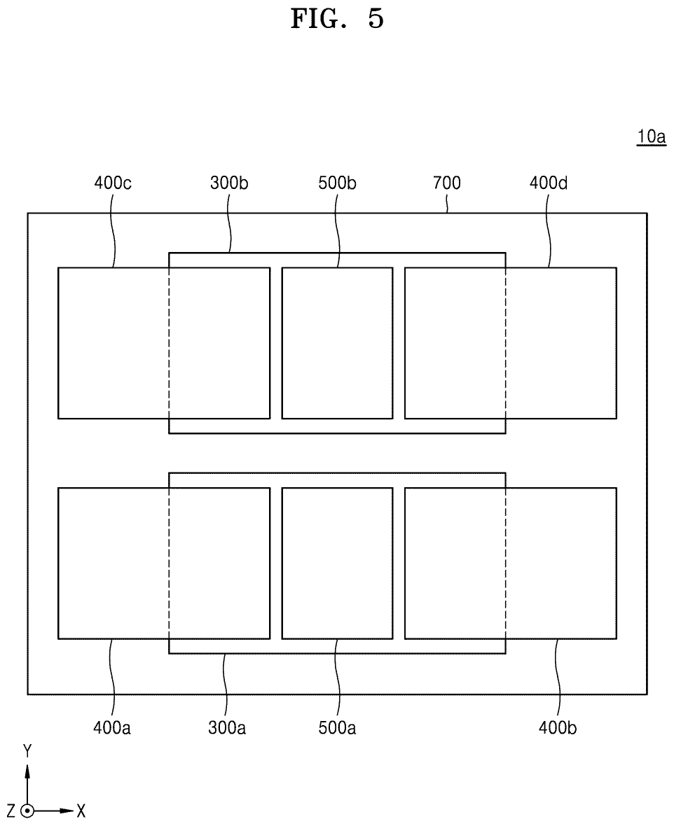

FIG. 5 is a plan view of a semiconductor package 10a according to another embodiment.

Referring to FIGS. 4 and 5, the semiconductor package 10 according to an embodiment shown in FIG. 4 may include a logic chip 300 disposed on the second redistribution structure 700, and a first memory device 400a and a second memory device 400b, each arranged to overlap with the logic chip 300 in the vertical direction (Z direction). The heat dissipation member 500 may overlap with the center of the logic chip 300 in the vertical direction (Z direction). Additionally, each of the first memory device 400a and the second memory device 400b may overlap an edge of the logic chip 300.

The semiconductor package 10a shown in FIG. 5 may include a first memory device 400a, a second memory device 400b, a third memory device 400c, a fourth memory device 400d, a first logic chip 300a, a second logic chip 300b, a first heat dissipation member 500a, and a second heat dissipation member 500b.

The first logic chip 300a and the second logic chip 300b may be spaced apart from each other in the second horizontal direction (Y direction). The first heat dissipation member 500a may overlap with the center of the first logic chip 300a in the vertical direction (Z direction). Additionally, each of the first memory device 400a and the second memory device 400b may overlap with an edge of the first logic chip 300a.

The second heat dissipation member 500b may overlap with the center of the second logic chip 300b in the vertical direction (Z direction). Additionally, each of the third memory device 400c and the fourth memory device 400d may overlap with an edge of the logic chip 300.

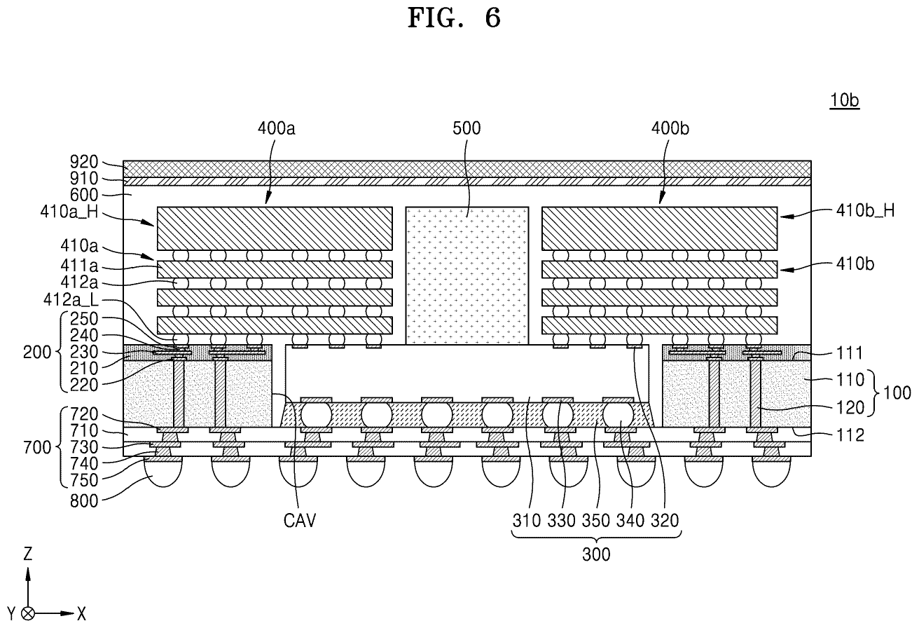

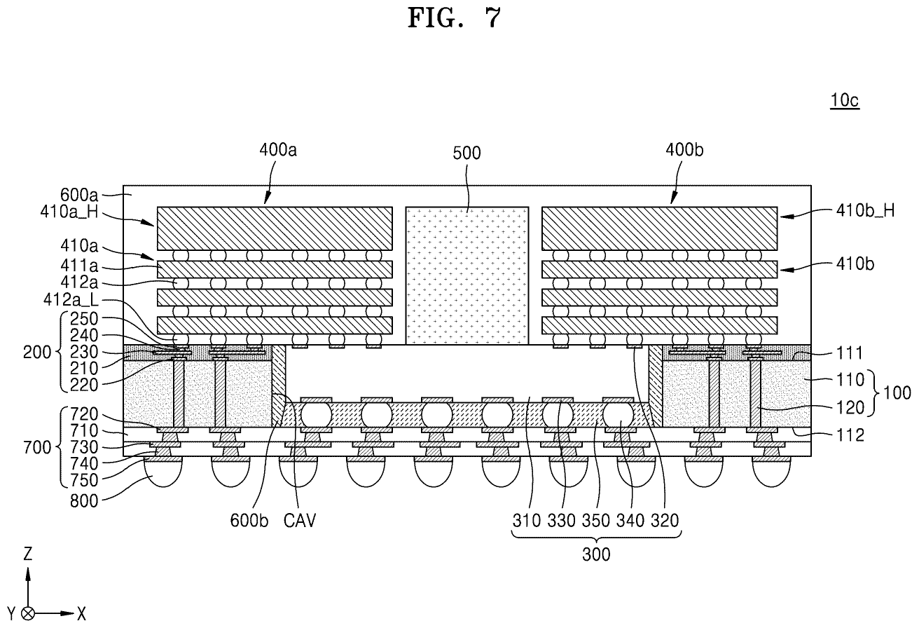

FIGS. 6 and 7 are cross-sectional views of a semiconductor package 10b and a semiconductor package 10c, respectively, according to embodiments.

The semiconductor package 10b shown in FIG. 6 is substantially the same as or similar to the semiconductor package 10 shown in FIG. 1, except that the semiconductor package 10b of FIG. 6 further includes a TIM 910 and a heat dissipation layer 920 disposed on the plurality of memory devices (e.g., the first memory device 400a and the second memory device 400b) and the heat dissipation member 500. Therefore, repeated descriptions of the components already mentioned with reference to FIG. 1 may be omitted or simplified below.

The semiconductor package 10b may further include a heat dissipation layer 920 disposed above the top surfaces of the first memory device 400a, the second memory device 400b, and the heat dissipation member 500. The heat dissipation layer 920 may include a heat dissipation plate, such as a heat slug or heat sink. In some embodiments, the heat dissipation layer 920 may surround the first memory device 400a, the second memory device 400b, and the heat dissipation member 500 on the top surface of the glass substrate 100.

Additionally, the semiconductor package 10b may further include the TIM 910. The TIM 910 may be interposed between the package encapsulation layer 600 and the heat dissipation layer 920.

The semiconductor package 10c shown in FIG. 7 is substantially the same as or similar to the semiconductor package 10 shown in FIG. 1, except that the semiconductor package 10c of FIG. 7 further includes a first package encapsulation layer 600a that seals the plurality of memory devices (e.g., the first memory device 400a and the second memory device 400b) and the heat dissipation member 500 and a second package encapsulation layer 600b that seals the logic chip 300 within the cavity CAV on the second redistribution structure 700. Therefore, repeated descriptions of the components already mentioned with reference to FIG. 1 may be omitted or simplified below.

The first package encapsulation layer 600a may seal the first memory device 400a, the second memory device 400b, and the heat dissipation member 500 on the second redistribution structure 700. The bottom surface of the first package encapsulation layer 600a may contact the top surface of the first redistribution structure 200 and the top surface of the logic chip 300. The second package encapsulation layer 600b may seal the logic chip 300 within the cavity CAV of the glass substrate 100 on the second redistribution structure 700. The second package encapsulation layer 600b may cover the sides of the glass substrate 100 and the sides of the first redistribution structure 200. Additionally, the second package encapsulation layer 600b may cover the underfill 350. According to an embodiment, the thermal conductivity of the second package encapsulation layer 600b may be greater than the thermal conductivity of the first package encapsulation layer 600a. When the amount of heat energy emitted from the logic chip 300 is greater than the amount of heat energy emitted from the plurality of memory devices (e.g., the first memory device 400a and the second memory device 400b), the thermal conductivity of the second package encapsulation layer 600b may be greater than the thermal conductivity of the first package encapsulation layer 600a. However, embodiments of the present disclosure are not limited thereto. Depending on an embodiment, the amount of heat energy emitted from the plurality of memory devices (e.g., the first memory device 400a and the second memory device 400b) may be greater than the amount of heat energy emitted from the logic chip 300. In this case, the thermal conductivity of the first package encapsulation layer 600a may be greater than the thermal conductivity of the second package encapsulation layer 600b.

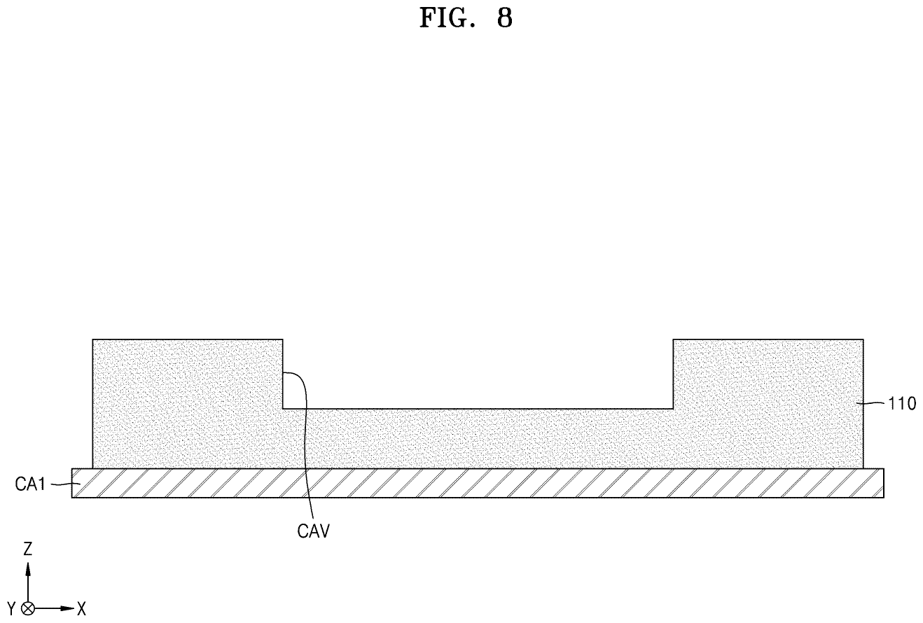

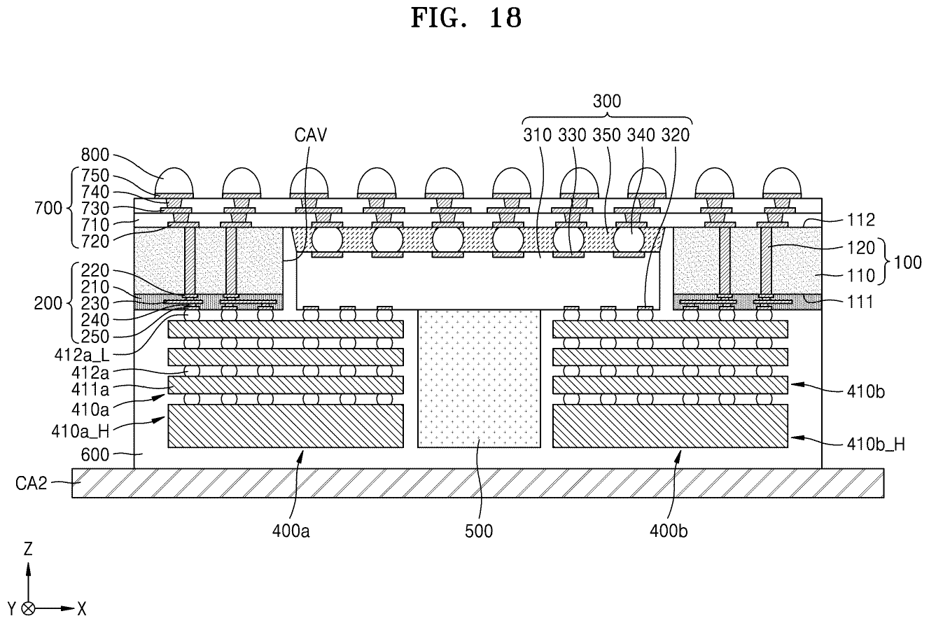

FIGS. 8 and 18 are cross-sectional views of a semiconductor package 10 to sequentially show a manufacturing process of the semiconductor package 10 according to an embodiment.

Referring to FIG. 8, a glass substrate 100 (or a glass body 110 thereof) is prepared. The glass substrate 100 (or the glass body 110 thereof) may be attached to a first carrier substrate CA1. Since the glass substrate 100 does not have adhesive properties, an adhesive material may be positioned between the glass substrate 100 and the first carrier substrate CA1. A cavity CAV with a certain depth may be formed in the vertical direction (Z direction) at the center of the glass substrate 100.

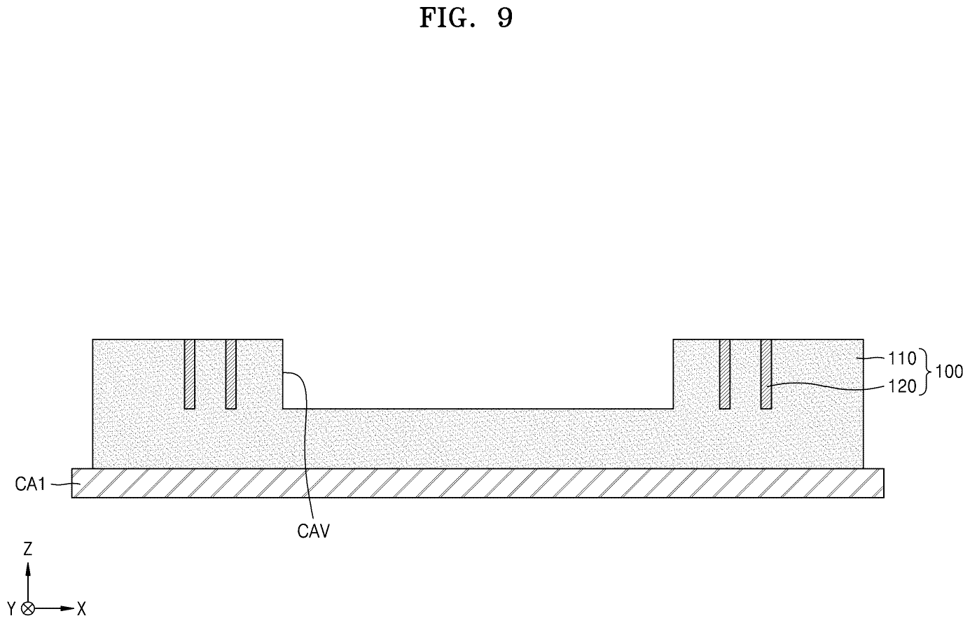

Referring to FIG. 9, holes extending in the vertical direction (Z direction) may be formed on the outer portion of the glass substrate 100 and through electrodes 120 may fill the holes with a conductive material. The holes may not reach the lowest surface of the glass substrate 100. Since the through electrodes 120 can completely fill the holes, the through electrodes 120 may have a cylindrical shape extending lengthwise in the vertical direction (Z direction).

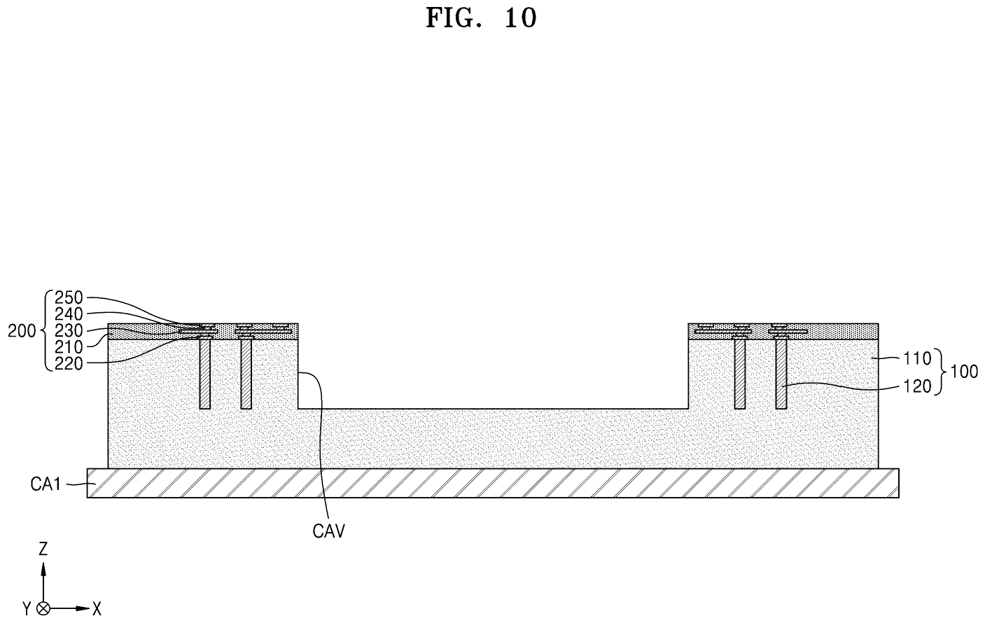

Referring to FIG. 10, the first redistribution structure 200 may be formed on the top surface of the glass substrate 100. The first redistribution structure 200 may be disposed on the top surface of the glass substrate 100, other than in the cavity CAV area.

The width of the first redistribution structure 200 in the lateral direction (X direction and/or Y direction) may correspond to the width of the glass body 110 excluding the cavity CAV area in the lateral direction (X direction and/or Y direction). The first redistribution structure 200 may include a first insulating layer 210, first lower connection pads 220, a first wiring pattern 230, first vias 240, and first upper connection pads 250. The length of the first insulating layer 210 in the vertical direction (Z direction) may be less than the length of the glass body 110 in the vertical direction (Z direction).

The first lower connection pads 220, the first wiring pattern 230, the first vias 240, and the first upper connection pads 250 may be buried inside the first insulating layer 210. The bottom surfaces of the first lower connection pads 220 may be flush with the bottom surface of the first insulating layer 210, and the first lower connection pads 220 may be in contact with the through electrodes 120.

According to an embodiment, the first wiring pattern 230 may be buried inside the first insulating layer 210 and extend in the lateral direction (X direction and/or Y direction). In FIG. 10, the first wiring pattern 230 is shown as one in the vertical direction (Z direction). However, depending on an embodiment, a plurality of first wiring patterns 230 may be arranged at different vertical levels. The plurality of first vias 240 may be in contact with the top surface and the bottom surface of the first wiring pattern 230, respectively.

According to an embodiment, the first vias 240 may be buried inside the first insulating layer 210 and extend in the vertical direction (Z direction). A plurality of the first vias 240 may be provided. The plurality of first vias 240 may be arranged at different vertical levels. Some of the plurality of first vias 240 between the first wiring pattern 230 and the first lower connection pads 220 may provide an electrical connection path between the first wiring pattern 230 and the first lower connection pads 220. In addition, others of the plurality of first vias 240 between the first upper connection pads 250 and the first wiring pattern 230 may provide an electrical connection path between the first upper connection pads 250 and the first wiring pattern 230. The first via 240 may have a tapered shape of which the diameter narrows towards the glass substrate 100 in the vertical direction (Z direction).

According to an embodiment, the top surfaces of the first upper connection pads 250 may be flush with the top surface of the first insulating layer 210.

The first redistribution structure 200 may be formed by repeating a patterning process.

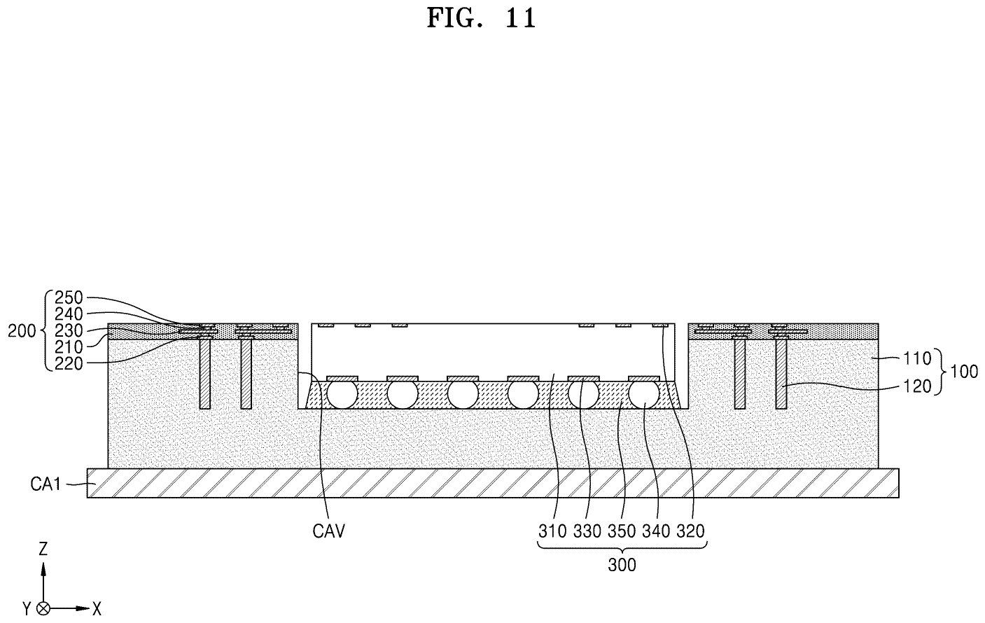

Referring to FIG. 11, the logic chip 300 may be mounted within the cavity CAV of the glass substrate 100. The logic chip 300 may be placed in the cavity CAV and spaced apart from the sides of the glass substrate 100.

The logic chip 300 may include a logic chip body 310, logic chip upper pads 320, logic chip lower pads 330, logic chip connection terminals 340, and underfill 350. According to an embodiment, the plurality of logic chip upper pads 320 may be arranged on the top surface of the logic chip body 310 in the lateral direction (X direction and/or Y direction). According to an embodiment, the top surfaces of the logic chip upper pads 320 may be flush with the top surface of the logic chip body 310. The top surface of the logic chip body 310 may be flush with the top surface of the first insulating layer 210 of the first redistribution structure 200.

According to an embodiment, the plurality of logic chip lower pads 330 may be arranged on or at the bottom surface of the logic chip body 310 in the lateral direction (X direction and/or Y direction). According to an embodiment, the bottom surfaces of the logic chip lower pads 330 may be flush with the bottom surface of the logic chip body 310, and the logic chip lower pads 330 may be in contact with the logic chip connection terminals 340.

According to an embodiment, the plurality of logic chip connection terminals 340 may be attached to the plurality of logic chip lower pads 330 of the logic chip body 310.

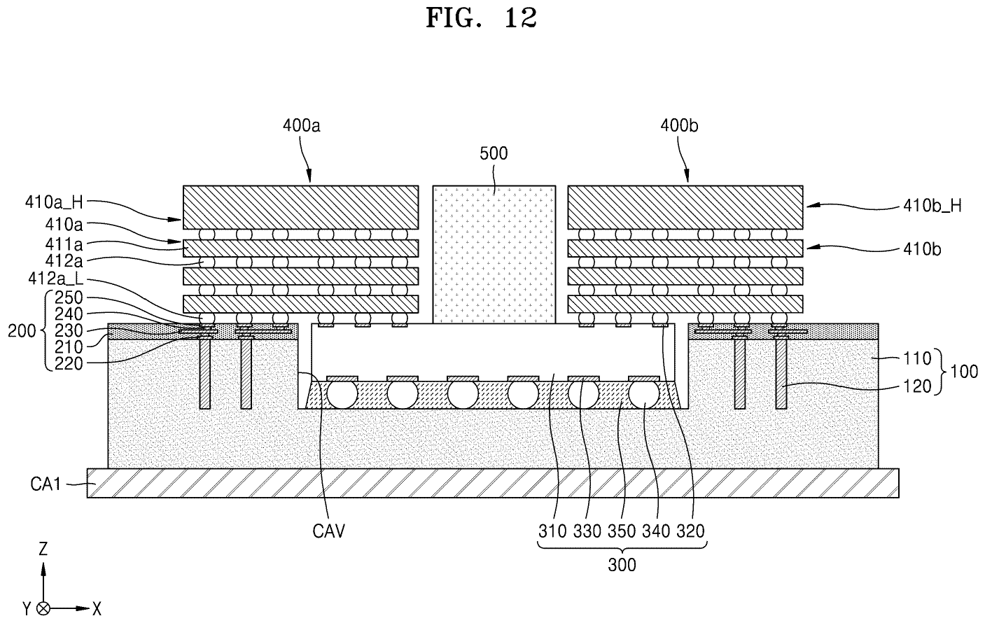

Referring to FIG. 12, the plurality of memory devices (e.g., the first memory device 400a and the second memory device 400b) may then be mounted on the first redistribution structure 200 and the logic chip 300. The plurality of memory devices (e.g., the first memory device 400a and the second memory device 400b) may include a first memory device 400a and a second memory device 400b spaced apart from the first memory device 400a in the first horizontal direction (X direction).

The first memory device 400a may include a plurality of memory chips 410a stacked in the vertical direction (Z direction), and a plurality of memory chip terminals 412a may be placed on the bottom surfaces of the plurality of memory chips 410a, respectively. Additionally, a memory chip placed at the top among the plurality of memory chips 410a may be defined as an uppermost memory chip 410a_H. Lowermost memory chip terminals 412a_L may be disposed on the bottom surface of a memory chip 410a located at the bottom. Some of the lowermost memory chip terminals 412a_L may be bonded to the first upper connection pads 250 of the first redistribution structure 200, and others thereof may be bonded to the logic chip upper pads 320 of the logic chip 300. The second memory device 400b may have substantially the same structure as the first memory device 400a.

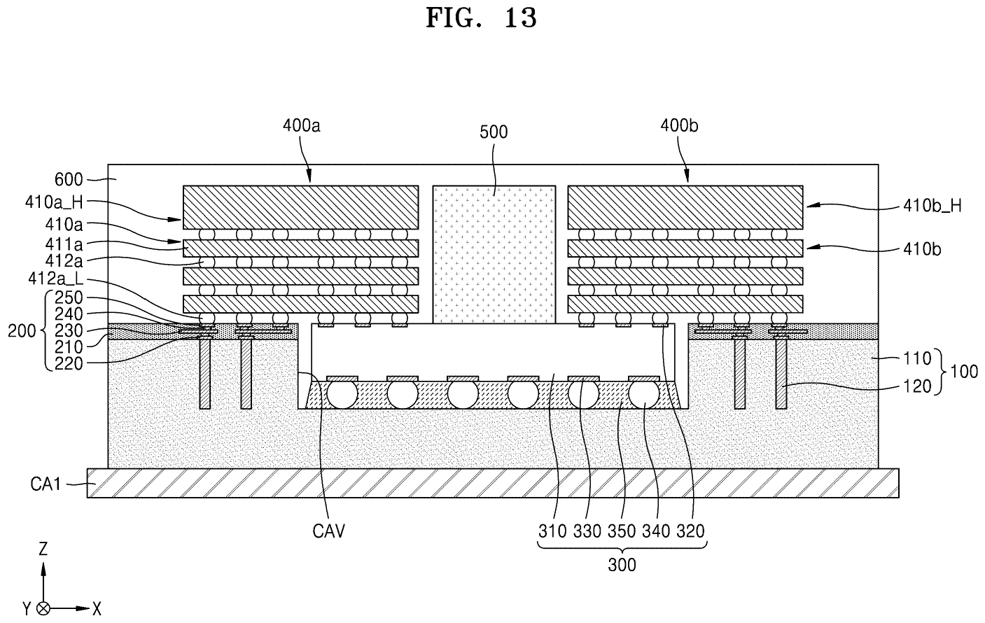

Referring to FIG. 13, a package encapsulation layer 600 that seals the logic chip 300, the heat dissipation member 500, and the plurality of memory devices (e.g., the first memory device 400a and the second memory device 400b) may be formed on the glass substrate 100 and the first redistribution structure 200. The package encapsulation layer 600 may cover the sides of the glass substrate 100 and the sides of the first redistribution structure 200 within the cavity CAV. The package encapsulation layer 600 may include, for example, EMC. The package encapsulation layer 600 may be mixed with fillers. The fillers may include, for example, silica. For example, the fillers may have a size of about several μm to about several tens μm or less and may have an average size of about 2 μm to about 10 μm. For example, the package encapsulation layer 600 may be mixed with fillers having a mass of about 80% to about 90%. That is, the ratio of fillers to the package encapsulation layer 600 may be about 80 wt % to about 90 wt %.

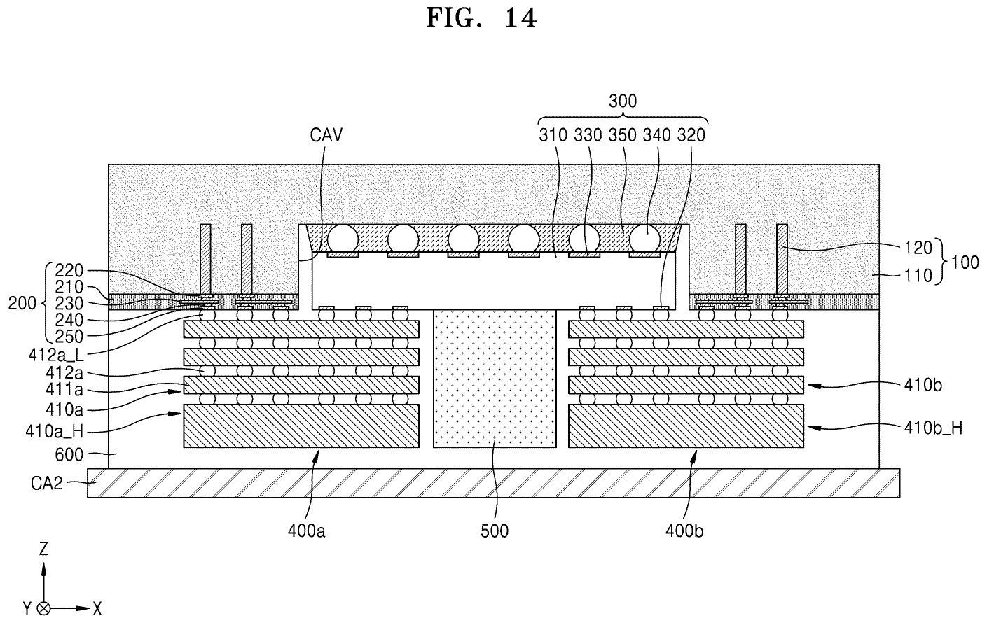

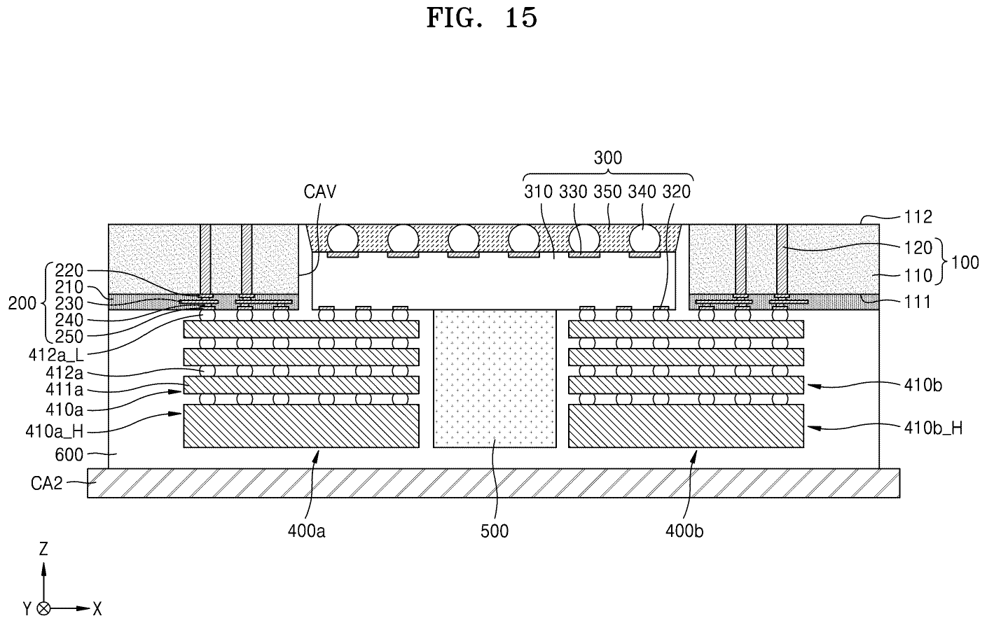

Referring to FIGS. 14 and 15, the first carrier substrate CA1 is removed and a second carrier substrate CA2 is attached to the top surface of the package encapsulation layer 600. Thereafter, the second carrier substrate CA2 may be turned over so that the bottom surface of the glass substrate 100 faces upwards in the vertical direction (Z direction).

Afterwards, the bottom surface (top surface in FIG. 14) of the glass substrate 100 may be ground. By grinding the bottom surface of the glass substrate 100, the bottom surface of the glass body 110 may be defined as the second surface 112 thereof, and the surface opposite to the second surface 112 of the glass body 110 may be defined as the first surface 111 thereof. By grinding the bottom surface of the glass substrate 100, the plurality of logic chip connection terminals 340 and the through electrodes 120 may be exposed.

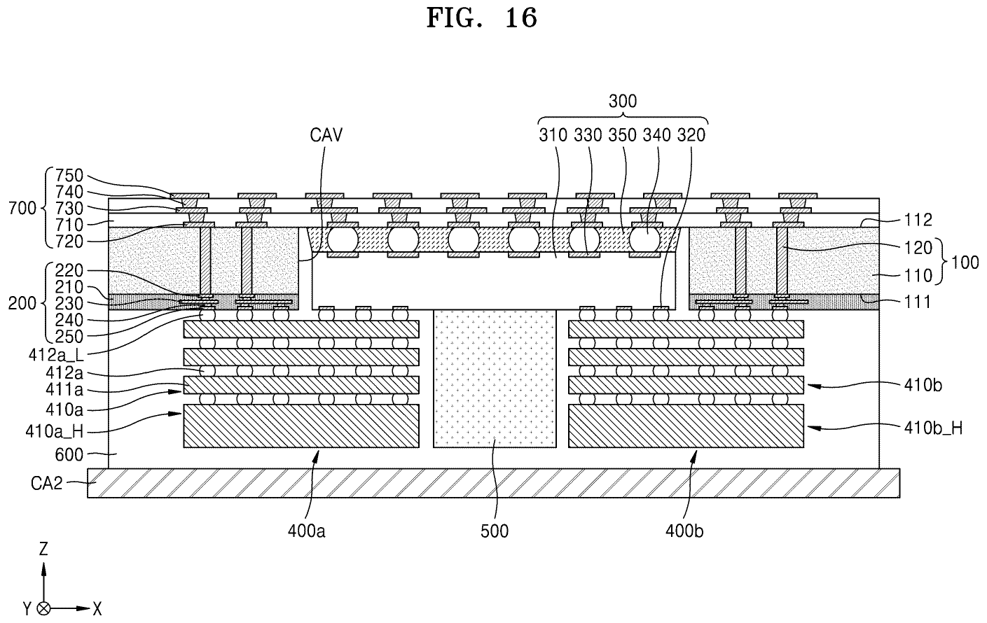

Referring to FIG. 16, the second redistribution structure 700 may be formed on the second surface 112 of the glass body 110.

The second redistribution structure 700 may be disposed on the second surface 112 of the glass body 110. The width of the second redistribution structure 700 in the lateral direction (X direction and/or Y direction) may correspond to the width of the glass body 110 in the lateral direction (X direction and/or Y direction). The second redistribution structure 700 may include a second insulating layer 710, second lower connection pads 750, a second wiring pattern 730, second vias 740, and second upper connection pads 720.

The second insulating layer 710 may cover the second surface 112 of the glass body 110, a portion of the package encapsulation layer 600, and the underfill 350. The second insulating layer 710 may be in contact with the second surface 112 of the glass body 110. The width of the second insulating layer 710 in the lateral direction (X direction and/or Y direction) may correspond to the width of the glass body 110 in the lateral direction (X direction and/or Y direction). Additionally, the length of the second insulating layer 710 in the vertical direction (Z direction) may be less than the length of the glass body 110 in the vertical direction (Z direction). The second insulating layer 710 may be formed through chemical vapor deposition (CVD), physical vapor deposition (PVD), or atomic layer deposition (ALD).

The second lower connection pads 750, the second wiring pattern 730, the second vias 740, and the second upper connection pads 720 may be buried inside the second insulating layer 710. A plurality of second insulating layers 710 may be provided. The plurality of second insulating layers 710 may be arranged at different vertical levels. The top surfaces of the second upper connection pads 720 may be flush with the top surface of each of the plurality of second insulating layers 710, and the uppermost ones of the second upper connection pads 720 may be in contact with the bottom surfaces of the through electrodes 120.

According to an embodiment, the second wiring pattern 730 may be buried inside the second insulating layer 710 and may extend in the lateral direction (X direction and/or Y direction). In FIG. 16, the second wiring pattern 730 is shown as one in the vertical direction (Z direction). However, depending on an embodiment, a plurality of second wiring patterns 730 may be arranged at different vertical levels.

According to an embodiment, the second vias 740 may be buried inside the second insulating layer 710 and extend in the vertical direction (Z direction). A plurality of the second vias 740 may be provided. The plurality of second vias 740 may be arranged at different vertical levels. Some of the plurality of second vias 740 between the second wiring pattern 730 and the second upper connection pads 720 may provide an electrical connection path between the second wiring pattern 730 and the second upper connection pads 720. In addition, the others of the plurality of second vias 740 between the second lower connection pads 750 and the second wiring pattern 730 may provide an electrical connection path between the second lower connection pads 750 and the second wiring pattern 730. The second via 740 may have a tapered shape of which the diameter narrows towards the glass substrate 100 in the vertical direction (Z direction).

According to an embodiment, the second lower connection pads 750, the second wiring pattern 730, the second vias 740, and the second upper connection pads 720 may be formed through a plating process or the like.

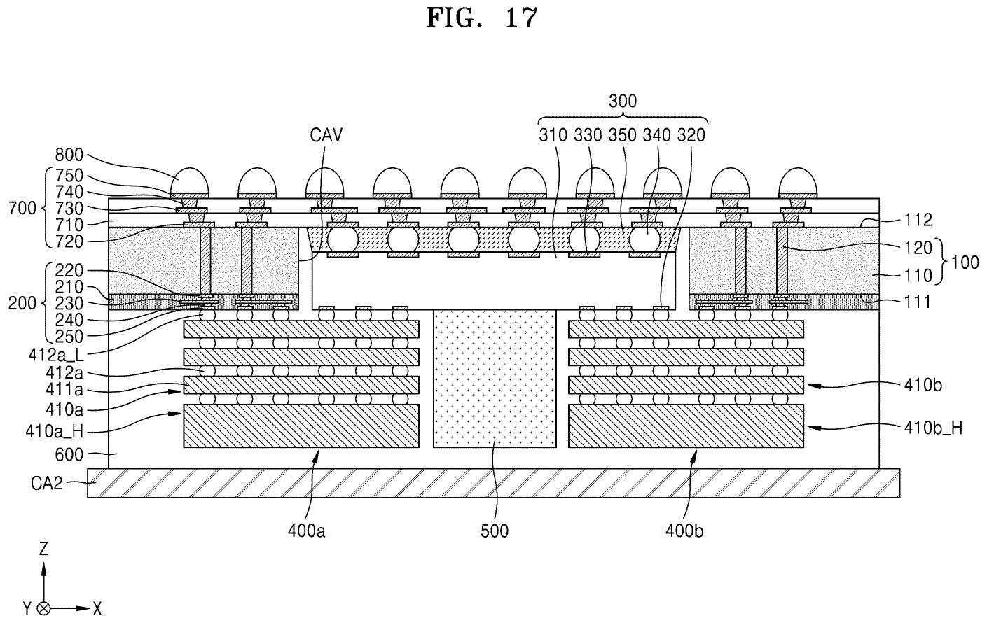

Referring to FIG. 17, the external connection terminals 800 may then be attached to the second lower connection pads 750.

Referring to FIG. 18, the semiconductor package may be completed by dicing the outer portions of the package encapsulation layer 600, the first insulating layer 210, the glass body 110, and the second insulating layer 710.

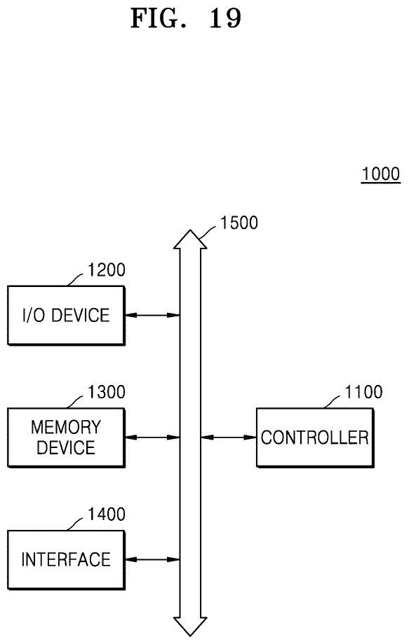

FIG. 19 is a schematic block diagram of an example of a memory system having a semiconductor package according to an embodiment.

Specifically, the memory system 1000 may be applied to a personal digital assistant (PDA), a portable computer, a web tablet, a wireless phone, a mobile phone, a digital music player, a memory card, or any device capable of transmitting and/or receiving information in a wireless environment.

The memory system 1000 includes a controller 1100, an input/output (I/O) device 1200, such as a keypad, a keyboard, and a display, a memory device (or memory chip) 1300, an interface 1400, and a bus 1500. The memory device 1300 communicates with the interface 1400 through the bus 1500.

The controller 1100 includes at least one microprocessor, a DSP, a microcontroller, or other processing devices similar thereto. The memory device 1300 may be used to store commands performed by the controller 1100. The I/O device 1200 may receive data or signals from outside the memory system 1000 or output data or signals outside the memory system 1000. For example, the I/O device 1200 may include a keyboard, a keypad, or a display device.

The memory device 1300 and the controller 1100 may include the semiconductor package 10, the semiconductor package 10a, the semiconductor package 10b, and/or the semiconductor package 10c according to the above-described embodiments. The memory device 1300 may further include other types of memory, volatile memory that can be accessed at any time, and various other types of memory. The interface 1400 may transmit data to a communication network or receive data from the communication network.

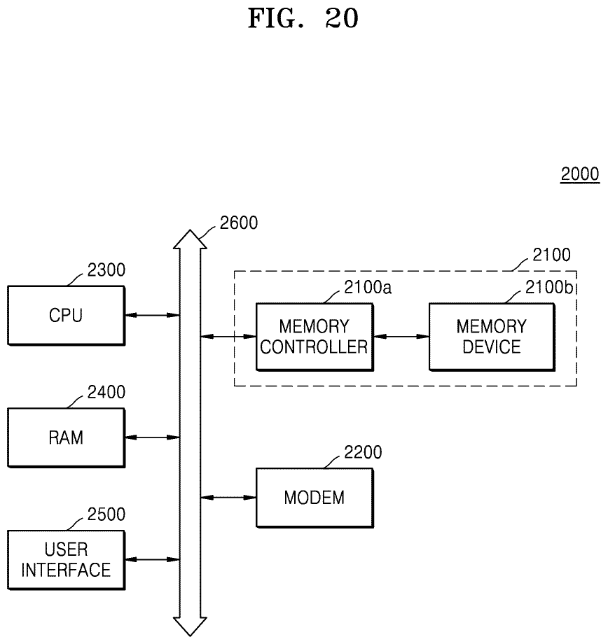

FIG. 20 is a schematic block diagram of an example of an information processing system having a semiconductor package according to an embodiment.

Specifically, the information processing system 2000 may be used on a mobile device or desktop computer. The information processing system 2000 may include a memory system 2100 including a memory controller 2100a and a memory device 2100b.

The information processing system 2000 includes a modulator and demodulator (MODEM) 2200, a CPU 2300, RAM 2400, and a user interface 2500, each electrically connected to a bus 2600. The data processed by the CPU 2300 or data input from the outside are stored in the memory system 2100.

The memory system 2100 including the memory controller 2100a and the memory device 2100b, the MODEM 2200, the CPU 2300, and the RAM 2400 may include the semiconductor package 10, the semiconductor package 10a, the semiconductor package 10b, and/or semiconductor package 10c according to an embodiment.

The memory system 2100 may be configured as a solid-state drive, in which case the information processing system 2000 can stably store a large amount of data in the memory system 2100. As reliability increases, the memory system 2100 may reduce resources required for error correction and provide a high-speed data exchange function to the information processing system 2000.

According to embodiments, an application chipset, an ISP, and an I/O device may further be provided to the information processing system 2000.

While non-limiting example embodiments have been particularly shown and described with reference to the drawings, it will be understood that various changes in form and details may be made therein without departing from the spirit and scope of the present disclosure.

What is claimed is:

1. A semiconductor package comprising:
a glass substrate including a cavity;
a logic chip within the cavity;
a memory device on the glass substrate and the logic chip;
a first redistribution structure between the memory device and the glass substrate, and connected to the memory device and the glass substrate;
a second redistribution structure below the glass substrate, and connected to the glass substrate and the logic chip; and
a package encapsulation layer that surrounds the memory device and the logic chip on the second redistribution structure.

2. The semiconductor package of claim 1, wherein the memory device overlaps with the logic chip in a direction intersecting a top surface of the logic chip.

3. The semiconductor package of claim 1, wherein the first redistribution structure comprises:
a first insulating layer in contact with a top surface of the glass substrate; and
a first conductive pad in the first insulating layer and in contact with the top surface of the glass substrate,
wherein the second redistribution structure comprises:
a second insulating layer in contact with a bottom surface of the glass substrate; and
a second conductive pad in the second insulating layer and in contact with the bottom surface of the glass substrate, and
wherein a width of the second conductive pad in a horizontal direction of the semiconductor package is greater than a width of the first conductive pad in the horizontal direction.

4. The semiconductor package of claim 3, wherein the first insulating layer comprises silicon oxide, and the second insulating layer comprises a polymer.

5. The semiconductor package of claim 1, wherein the glass substrate comprises a glass body and a through electrode penetrating the glass body in a direction intersecting a top surface of the glass body, and
wherein the through electrode is connected to the first redistribution structure and the second redistribution structure.

6. The semiconductor package of claim 1, wherein the memory device comprises a memory chip terminal connected to the first redistribution structure,
wherein the logic chip comprises a logic chip terminal connected to the second redistribution structure, and
wherein a diameter of the logic chip terminal is greater than a diameter of the memory chip terminal.

7. The semiconductor package of claim 1, wherein, within the cavity, the glass substrate is spaced apart from the logic chip in a horizontal direction of the semiconductor package.

8. The semiconductor package of claim 1, wherein a top surface of the first redistribution structure and a top surface of the logic chip are on a same plane.

9. The semiconductor package of claim 1, further comprising a heat dissipation member attached to a top surface of the logic chip and spaced apart from the memory device in a horizontal direction of the semiconductor package.

10. The semiconductor package of claim 1, wherein the package encapsulation layer is on sides of the glass substrate and sides of the logic chip within the cavity.

11. A semiconductor package comprising:
a glass substrate including a cavity, the glass substrate comprising a glass body that comprises a first surface and a second surface opposite to the first surface;
a logic chip within the cavity;
a pair of memory devices on the first surface of the glass body and the logic chip, the pair of memory devices spaced apart from each other in a horizontal direction of the semiconductor package;
a first redistribution structure between the pair of memory devices and the first surface of the glass body;
a second redistribution structure on the second surface of the glass body, and connected to the glass substrate and the logic chip;
a heat dissipation member between the pair of memory devices on a top surface of the logic chip; and
a first package encapsulation layer surrounding the pair of memory devices and the heat dissipation member on the second redistribution structure.

12. The semiconductor package of claim 11, wherein each memory device from among the pair of memory devices comprises a plurality of memory chips stacked in a vertical direction of the semiconductor package.

13. The semiconductor package of claim 11, wherein the glass substrate further comprises a through electrode extending from the first surface to the second surface of the glass body, and the through electrode is connected to the first redistribution structure and the second redistribution structure.

14. The semiconductor package of claim 11, wherein the logic chip comprises:
a logic chip connection terminal connected to the second redistribution structure; and
an underfill surrounding the logic chip connection terminal within the cavity.

15. The semiconductor package of claim 11, further comprising:
a thermal interface material in contact with top surfaces of the pair of memory devices and a top surface of the heat dissipation member; and
a heat dissipation layer on the thermal interface material.

16. The semiconductor package of claim 11, wherein the pair of memory devices overlap with outer edges of the logic chip in a horizontal view, and
wherein the heat dissipation member overlaps with a center of the logic chip in the horizontal view.

17. The semiconductor package of claim 11, further comprising a second package encapsulation layer surrounding the logic chip within the cavity,
wherein the second package encapsulation layer forms an interface with the first package encapsulation layer.

18. The semiconductor package of claim 11, wherein a side of the first redistribution structure is in contact with the first package encapsulation layer and is spaced apart from the logic chip in the horizontal direction.

19. A semiconductor package comprising:
a glass substrate including a cavity, the glass substrate comprising a glass body that comprises a first surface and a second surface opposite to the first surface, and the glass substrate further comprising a through electrode extending from the first surface to the second surface;
a logic chip within the cavity;
a first memory device on the first surface of the glass body and the logic chip and comprising a plurality of first semiconductor chips stacked in a vertical direction of the semiconductor package;
a first redistribution structure between the first memory device and the first surface of the glass body and connected to the first memory device and the glass substrate;
a second redistribution structure on the second surface of the glass body and connected to the glass substrate and the logic chip;
a second memory device spaced from the first memory device in a horizontal direction of the semiconductor package and comprising a plurality of second semiconductor chips stacked in the vertical direction;
a heat dissipation member between the first memory device and the second memory device on a top surface of the logic chip; and
a package encapsulation layer surrounding the first memory device, the second memory device, and the heat dissipation member on the second redistribution structure,
wherein the first redistribution structure comprises:
a first insulating layer in contact with the first surface of the glass body; and
a first conductive pad in the first insulating layer and bonded to the through electrode,
wherein the second redistribution structure comprises:
a second insulating layer in contact with the second surface of the glass body; and
a second conductive pad in the second insulating layer and bonded to the through electrode, and
wherein a width of the second conductive pad is greater than a width of the first conductive pad in the horizontal direction.

20. The semiconductor package of claim 19, wherein the first memory device is attached to a lowermost first semiconductor chip among the plurality of first semiconductor chips and comprises a memory chip terminal connected to the first redistribution structure, and
wherein the logic chip comprises a logic chip terminal connected to the second redistribution structure.
